(19) United States
(12) Patent Application Publication
(10) Pub. No.: US 2022/0109010 A1
(43) Pub. Date: Apr. 7, 2022

(54) ARRAY SUBSTRATE, TEST METHOD OF FILM LAYER STRESS, AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Jiaqing HE, Wuhan (CN); Hao PENG, Wuhan (CN)

(21) Appl. No.: 17/261,389

(22) PCT Filed: Apr. 28, 2020
(86) PCT No.: PCT/CN2020/087398

§ 371 Date: Jan. 19, 2021

(30) Foreign Application Priority Data
Jan. 7, 2020 (CN) 202010012504.0

(51) Int. Cl. H01L 27/12; G01L 1/14; G01L 1/22; G01L 1/24

(52) U.S. Cl. CPC H01L 27/1255; G01L 1/14; G01L 1/142; H01L 27/1218; G01L 1/24; H01L 27/124; G01L 1/22

(57) ABSTRACT

An array substrate, a test method of a film layer stress, and a display panel are provided. The array substrate includes: a base substrate; a first film layer on the base substrate, the first film layer provided with a first mounting groove; and a first strain sensor arranged in the first mounting groove. The first strain sensor is used to detect a stress of the first film layer.

### CROSS REFERENCE TO RELATED APPLICATIONS

The present application claims the priority of China Patent Application No. 202010012504.0, filed with the National Intellectual Property Administration on Jan. 7, 2020, titled “ARRAY SUBSTRATE, TEST METHOD OF FILM LAYER STRESS, AND DISPLAY PANEL”, which is incorporated by reference in the present application in its entirety.

### 1. FIELD OF DISCLOSURE

The present application relates to a field of display technology and in particular, to an array substrate, a test method of a film layer stress, and a display panel.

### 2. DESCRIPTION OF RELATED ART

At present, there has been a trend for developing flexible display screens, such as rollable screens and foldable screens, in the display field.

In conventional techniques, flexible display screens generally include a substrate, a thin film transistor (TFT) structure, a light-emitting layer, an encapsulation layer, and a modular structure. When being rolled or bent, a laminate structure inside the flexible display screen is stressed to cause problems like film breakage, peeling, poor electrical properties, and uneven brightness, which may lead to different degrees of device damage such as display defects or display failures.

However, in development, testing, film optimization, and product usage of the flexible display screen, stresses of film layers inside the flexible display screen under different rolled and bent conditions are still lacking in quantitative testing methods, which makes it impossible to monitor in real time the stresses in a flexible display panel during use, and to provide early warning of damage to the flexible display panel.

The present application provides an array substrate, a test method of film layer stress, and a display panel to quantitatively test a stress condition of a film layer in a flexible display panel in a rolled or bent state, and thus can promptly provide early warning of damage of the flexible display panel.

### SUMMARY

In one aspect, the present application provides an array substrate, comprising:

a base substrate;

a first film layer disposed on the base substrate, a first mounting groove defined in the first film layer; and

a first strain sensor disposed in the first mounting groove, wherein the first strain sensor is configured to detect a stress of the first film layer.

The first strain sensor comprises a resistive strain sensor, a capacitive strain sensor, an inductive strain sensor, or an optical strain sensor.

Material of the first strain sensor is the same as material of the first film layer.

The first film layer is a low-temperature polycrystalline silicon (LTPS) layer, a gate layer, a source/drain layer, or an anode layer.

The base substrate comprises a bending region, the array substrate comprises one or multiple first strain sensors, and at least one of the first strain sensors is disposed in the bending region.

The array substrate comprises multiple first strain sensors, and the first strain sensors are arranged in an array on the base substrate.

The array substrate further comprises an insulating layer, a second film layer, and a second strain sensor, the insulating layer is disposed on the first film layer and the first strain sensor, the second film layer is disposed on the insulating layer, a second mounting groove is defined in the second film layer, and the second strain sensor is disposed in the second mounting groove, wherein the second strain sensor is configured to detect a stress of the second film layer.

The first strain sensor comprises an input end and an output end, the input end of the first strain sensor is electrically connected to an external circuit board, the external circuit board is configured to provide an operating voltage to the first strain sensor, and the output end of the first strain sensor is electrically connected to an external sensor control unit.

The array substrate further comprises a first connection line and a second connection line, the first connection line and the second connection line are arranged in a same layer as the first strain sensor, the first connection line is configured for establishing an electrical connection between the input end of the first strain sensor and the external circuit board, and the second connection line is configured for establishing an electrical connection between the output end of the first strain sensor and the external sensor control unit.

In another aspect, the present application further provides a test method of a film layer stress for use in an array substrate, the array substrate comprising: a base substrate; a first film layer disposed on the base substrate, a first mounting groove defined in the first film layer; and a first strain sensor disposed in the first mounting groove, wherein the first strain sensor is configured to detect a stress of the first film layer, the test method of the film layer stress comprising following steps:
activating the first strain sensor;
bending or rolling the array substrate, and acquiring an amount of change in a detection parameter of the first strain sensor; and
determining a stress of the first film layer according to the amount of change.

Determining the stress of the first film layer according to the amount of change comprises:

converting the amount of change to a corresponding current change amount or a corresponding voltage change amount;

determining an amount of strain of the first film layer according to the current change amount or the voltage change amount; and

determining the amount of stress of the first film layer according to the amount of strain of the first film layer.

In still another aspect, the present application further provides a display panel comprising an array substrate, the array substrate comprising:

a base substrate;

a first film layer disposed on the base substrate, wherein a first mounting groove is defined in the first film layer; and

a first strain sensor disposed in the first mounting groove, wherein the first strain sensor is configured to detect a stress of the first film layer.

The first strain sensor comprises a resistive strain sensor, a capacitive strain sensor, an inductive strain sensor, or an optical strain sensor.

Material of the first strain sensor is the same as material of the first film layer.

The first film layer is a low-temperature polycrystalline silicon (LTPS) layer, a gate layer, a source/drain layer, or an anode layer.

The base substrate comprises a bending region, the display panel comprises one or multiple first strain sensors, and at least one of the first strain sensors is disposed in the bending region.

The display panel comprises multiple first strain sensors, and the first strain sensors are arranged in an array on the base substrate.

The array substrate further comprises an insulating layer, a second film layer, and a second strain sensor, the insulating layer is disposed on the first film layer and the first strain sensor, the second film layer is disposed on the insulating layer, a second mounting groove is defined in the second film layer, and the second strain sensor is defined in the second mounting groove, wherein the second strain sensor is configured to detect a stress of the second film layer.

The first strain sensor comprises an input end and an output end, the input end of the first strain sensor is electrically connected to an external circuit board, the external circuit board is configured to provide an operating voltage to the first strain sensor, and the output end of the first strain sensor is electrically connected to an external sensor control unit.

The array substrate further comprises a first connection line and a second connection line, the first connection line and the second connection line are arranged in a same layer as the first strain sensor, the first connection line is configured for establishing an electrical connection between the input end of the first strain sensor and the circuit board, and the second connection line is configured for establishing an electrical connection between the output end of the first strain sensor and the sensor control unit.

### Advantages of the Present Invention

Compared to conventional techniques, the array substrate of the present application includes the base substrate, the first film layer, and a first strain sensor. The first strain sensor is configured to detect the stress of the first film layer. By having the strain sensor in a film structure of the array substrate of the flexible display panel, the present application can quantitatively detect the film layer stress inside the flexible display panel in a rolled or bent state, and then can promptly provide early warning of damage to the flexible display panel.

### BRIEF DESCRIPTION OF DRAWINGS

The following detailed description of the present application will make the technical solutions and the advantages of the present application obvious in conjunction with the accompanying drawings and specific embodiments.

FIG. 1 is a schematic structural view illustrating an array substrate according to one embodiment of the present application;

FIG. 2 is another schematic structural view illustrating the array substrate according to one embodiment of the present application;

FIG. 3 is still another schematic structural view illustrating the array substrate according to one embodiment of the present application;

FIG. 4 is yet another schematic structural view illustrating the array substrate according to one embodiment of the present application;

FIG. 5 is yet still another schematic structural view illustrating the array substrate according to one embodiment of the present application;

FIG. 6 is a schematic distribution view illustrating first strain sensors in the array substrate according to one embodiment of the present application;

FIG. 7 is another schematic distribution view illustrating the first strain sensors in the array substrate according to one embodiment of the present application;

FIG. 8 is still another schematic distribution view illustrating the first strain sensors in the array substrate according to one embodiment of the present application;

FIG. 9 is a schematic structural view illustrating an optical strain sensor according to one embodiment of the present application;

FIG. 10 is a schematic process flow diagram illustrating a test method of a film layer stress according to one embodiment of the present application; and

FIG. 11 is a schematic structural view illustrating a display panel according to one embodiment of the present application.

### DETAILED DESCRIPTION OF EMBODIMENTS

The present application is described in detail below with reference to the drawings and embodiments. In particular, the following embodiments are only used to illustrate the present application, but are not intended to limit the scope of the present application. Also, the following embodiments are only some of the embodiments of the present application but not all the embodiments. All other embodiments obtained by persons of ordinary skill in the art without creative efforts shall fall within the protection scope of the present application.

At present, when a flexible display panel is rolled up or bent, due to stress, an internal laminate structure may suffer from film breakage, peeling, poor electrical properties, uneven brightness, and etc., which can lead to different degrees of damages like display defects or display failures. However, in development, testing, film optimization, and product usage of the flexible display panel, stresses of film layers inside a flexible display screen under different rolled and bent conditions are still lacking in quantitative testing methods, which makes it impossible to monitor in real time the stresses in the flexible display panel during use, and provide early warning of damage to the flexible display panel. In order to solve the above technical problems, the technical solution of the present application is to provide a strain sensor in a film layer structure of an array substrate of the flexible display panel to quantitatively test the stresses of film layers inside the flexible display panel in a rolled or bent state, and then promptly provide early warning of damage of the flexible display panel.

Please refer to FIG. 1, which is a schematic structural view illustrating an array substrate according to one embodiment of the present application. As shown in FIG. 1, the array substrate 100 includes a base substrate 101, and a first film layer 102 and a first strain sensor 103 on the base substrate 101, wherein the first film layer 102 is provided with a first mounting groove 102a. The first strain sensor 103 is disposed in the first mounting groove 102a and is configured to detect a stress of the first film layer 102.

The base substrate 101 can be a flexible substrate, and material of the base substrate 101 can be organic polymer such as one of polyimide, polycarbonate, polyethylene terephthalate, a polyethersulfone substrate. In other embodiments, the above-mentioned base substrate 101 can also have a laminate structure. For example, the base substrate 101 can include a polyimide substrate, a barrier layer and a buffer layer stacked sequentially from bottom to top, wherein material of the barrier layer can be silicon oxide, and material of the buffer layer can be SiNx, SiOx, or other suitable dielectric material. The first film layer 102 can be a low-temperature polycrystalline silicon (LTPS) layer, a gate layer, a source/drain layer, or an anode layer of the array substrate 100. Because the LTPS layer, the gate layer, the source/drain layer, and the anode layer of the array substrate 100 generally are patterned film layers, so the first mounting groove 102a can be an opening in the patterned film layer, and there is no need to change a conventional array substrate film formation process.

In the present embodiment, the base substrate 101 under the first film layer 102 can be exposed through the first mounting groove 102a. In other words, the first strain sensor 103 is disposed in an area of the base substrate 101, which is not covered by the first film layer 102, so that upper and lower film layer structures where the first strain sensor 103 is located can be completely consistent with upper and lower film layer structures where the first film layer 102 is located, and as a result, the first strain sensor 103 can more realistically reflect actual strain and stress conditions of the first film layer 102 inside the array substrate 100. Specifically, when the array substrate 100 is deformed by rolling, bending, or the like, the first strain sensor 103 is deformed by force and converts an amount of deformation into other types of physical signals (e.g., a resistance change, a capacitance change, a change rate of inductance, or changes of optical parameters), and then the converted physical signals can be transmitted to an external sensor control unit, so that the external sensor control unit can convert the converted physical signals into readable signals (e.g., a voltage signal and a current signal), and the stress of the first film layer 102 can be determined.

Specifically, the first strain sensor 103 can include one or more of a resistive strain sensor, a capacitive strain sensor, an inductive strain sensor, or an optical strain sensor. Among them, the resistive strain sensor can convert the amount of deformation into a resistance change amount, the capacitive strain sensor can convert the amount of deformation into a capacitance change amount, the inductive strain sensor can convert the amount of deformation into an inductance change rate, and the optical strain sensor can convert the amount of deformation into changes in optical parameters (e.g., the optical power, phase, and wavelength).

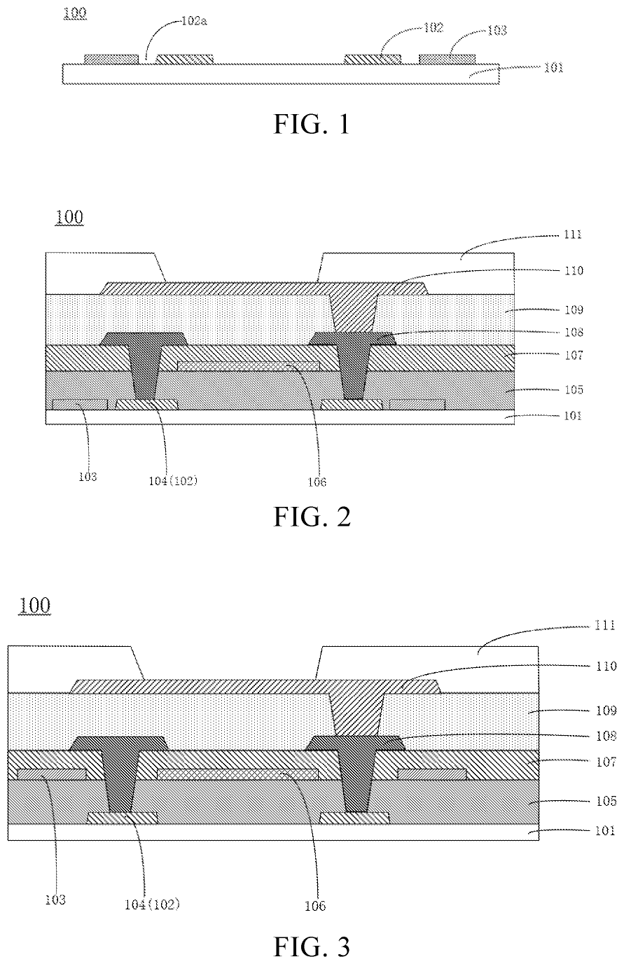

In one embodiment, as shown in FIG. 2, the first film layer 102 can be a low-temperature polycrystalline silicon (LTPS) layer 104 of the array substrate 100. Specifically, the array substrate 100 can comprise the LTPS layer 104 (the first film layer 102), a gate insulating layer 105 on the first strain sensor 103, and a gate layer 106, an interlayer dielectric layer 107, a source/drain layer 108, a planarization layer 109, an anode layer 110, and a pixel definition layer 111 sequentially disposed on the gate insulating layer 105. In some alternative embodiments, the first film layer 102 can also be the gate layer 106 (as shown in FIG. 3), the source/drain layer 108, or the anode layer 110 of the array substrate 100.

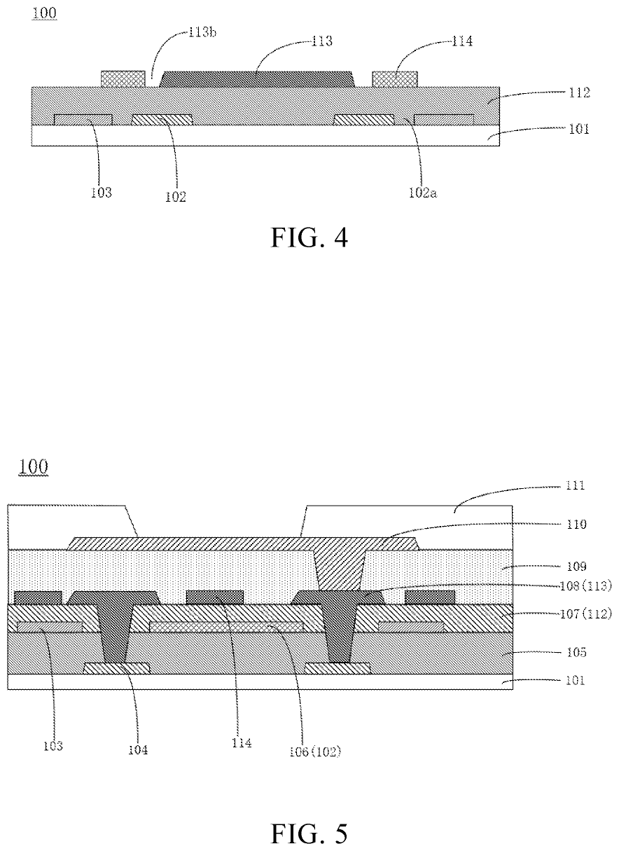

In some embodiments, as shown in FIG. 4, the above array substrate 100 also can include an insulating layer 112, a second film layer 113, and a second strain sensor 114, wherein the insulating layer 112 is arranged on the first film layer 102 and the first strain sensor 103, and the second film layer 113 and the second strain sensor 114 are arranged on the insulating layer 112. The second film layer 113 is provided with a second mounting groove 113b, and the second strain sensor 114 is disposed in the second mounting groove 113b. The second strain sensor 114 is used to detect a stress of the second film layer 113.

The insulating layer 112 arranged under the second film layer 113 can be exposed through the second mounting groove 113b, that is, the second strain sensor 114 is disposed in an area of the insulating layer 112, which is not covered by the second film layer 113. Working principles of the second strain sensor 114 are the same as those of the above-mentioned first strain sensor 103, so a detailed description thereof is omitted herein for brevity. In addition, the second strain sensor 114 can also include one or more of a resistive strain sensor, a capacitive strain sensor, an inductive strain sensor, or an optical strain sensor.

Specifically, the first film layer 102 and the second film layer 113 can be any two of the LTPS layer 104, the gate layer 106, the source/drain layer 108, and the anode layer 110 of the array substrate 100. For example, as shown in FIG. 5, the first film layer 102 is the gate layer 106, the second film layer 113 is the source/drain layer 108, and the above-mentioned insulating layer 112 is the interlayer dielectric layer 107.

It should be noted that the first film layer 102 or the second film layer 113 is not limited to one of the LTPS layer 104, the gate layer 106, the source/drain layer 108, and the anode layer 110 of the array substrate 100. In practice, a stress sensor can be disposed in any film layer of the array substrate 100 according to the actual needs of a stress test to detect a stress of a corresponding film layer. In addition, the film layer provided with the strain sensor is not limited to the above-mentioned first film layer and second film layer. In practice, the number of the film layers provided with the strain sensors can be increased according to an actual need of a stress test. For example, the strain sensors can be installed in at least three of the LTPS layer 104, the gate insulating layer 105, the gate layer 106, the interlayer dielectric layer 107, the source/drain layer 108, the planarization layer 109, the anode layer 110, and the pixel definition layer 111 of the array substrate 100.

When the first film layer 102 or the second film layer 113 is one of the LTPS layer 104, the gate layer 106, the source/drain layer 108, and the anode layer 110 of the array substrate 100, the LTPS layer 104, the gate layer 106, the source/drain layer 108, and the anode layer 110 generally are patterned film layers, so the first mounting groove 102a or the second mounting groove 113b can be an opening in the patterned film layer. In other words, the first strain sensor 103 or the second strain sensor 114 is directly disposed in the opening of the patterned LTPS layer 104, the gate layer 106, the source/drain layer 108, or the anode layer 110. When the first film layer 102 or the second film layer 113 is one of the gate insulating layer 105, the interlayer dielectric layer 107, the planarization layer 109, and the pixel definition layer 111 of the array substrate 100, an etching process can be performed first to pattern the gate insulating layer 105, the interlayer dielectric layer 107, the planarization layer 109, or the pixel definition layer 111 to obtain the first mounting groove 102a or the second mounting groove 113b, and then the above-mentioned first strain sensor 103 or the second strain sensor 114 is disposed in the first mounting groove 102a or the second mounting groove 113b.

In the above embodiments, the first strain sensor 103 and the second strain sensor 114 can be produced by 3D printing, a template method, self-assembly, controllable assembly, a sol-gel method, a pressing molding method, and etc. Alternatively, the first strain sensor 103 and the second strain sensor 114 can be produced by means of conventional array substrate film layer manufacturing processes. In addition, the first strain sensor 103 and the second strain sensor 114 can be produced by using a conventional array substrate film layer material, or can be produced by using other metal materials, non-metal materials, composite materials, and etc.

In the above embodiment, the material of the first strain sensor 103 and the material of the first film layer 102 can be the same or different. For example, please continue to refer to FIG. 2, if the first film layer 102 is the LTPS layer 104 of the array substrate 100, the material of the first strain sensor 103 and the material of the LTPS layer 104 can be the same or different; and when the the material of the first strain sensor 103 is the same as the material of the LTPS layer 104, the first strain sensor 103 can be a resistive strain sensor composed of a semiconductor resistor, or an optical strain sensor composed of a semiconductor grating, and the first strain sensor 103 and the LTPS layer 104 can be produced in a same one patterning process.

For another example, please continue to refer to FIG. 3, if the first film layer 102 is the gate layer 106 of the array substrate 100, the material of the first strain sensor 103 and the material of the gate layer 106 can be the same or different. Furthermore, when the material of the first strain sensor 103 is the same as the material of the gate layer 106, the first strain sensor 103 can be a resistive strain sensor composed of a metal resistor, an optical strain sensor composed of a metal grating, or an inductive strain sensor composed of a metal trace, and the first strain sensor 103 and the gate layer 106 can also be produced in a same one patterning process.

It should be noted that the material of the second strain sensor 114 and the material of the second film layer 113 can be the same or different, and for specific implementation details, please refer to the above description of the material of the first strain sensor 103, so a detailed description is omitted herein for brevity.

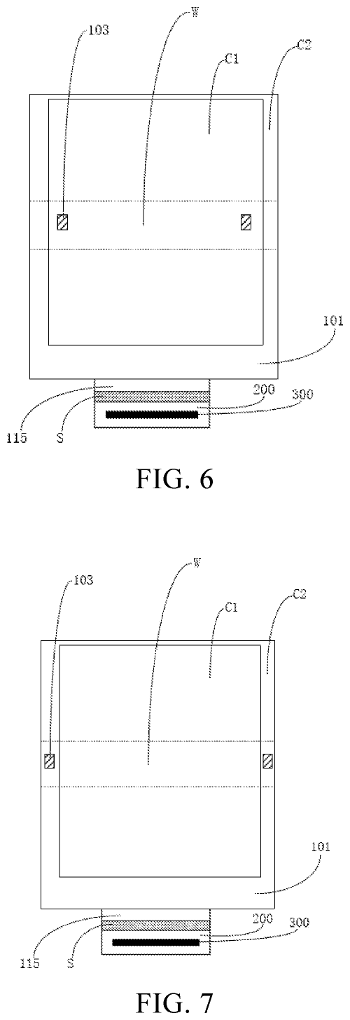

In the above embodiment, as shown in FIG. 6, the base substrate 101 can include a bending region W, there can be one or multiple first strain sensors 103, and at least one first strain sensor 103 is disposed in the bending region W. Similarly, there can be one or more second strain sensors 114, and the at least one second strain sensor 114 is arranged in the bending region W, so that a stress condition of an upper film layer in the bending region W can be monitored in real time when being bent or rolled. In addition, please continue to refer to FIG. 6, the base substrate 101 can further comprise a display region C1 and a non-display region C2 around the display region C1, wherein the first strain sensor 103 and the second strain sensor 114 can be arranged in the display region C1, and can also be arranged in the non-display region C2. In addition, in some embodiments, the first strain sensor 103 or/and the second strain sensor 114 can be arranged in an overlapping area (as shown in FIG. 6) between the display region C1 and the bending region W, and the first strain sensor 103 or/and the second strain sensor 114 can also be located in an overlapping area (as shown in FIG. 7) between the non-display region C2 and the bending region W.

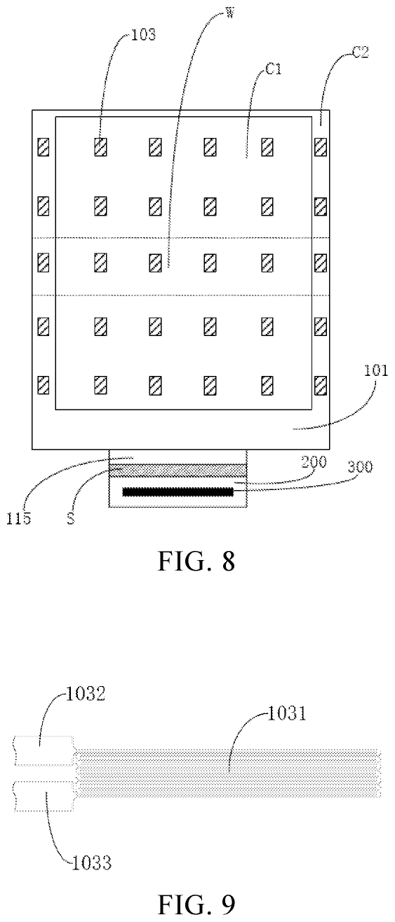

Specifically, as shown in FIG. 8, when there are multiple first strain sensors 103, the multiple first strain sensors 103 can be arranged in an array on the base substrate 101. Similarly, when there are multiple second strain sensors 114, the second strain sensors 114 can also be arranged in an array on the base substrate 101, so that a strain distribution of an entire film layer or a local area of the film layer can be monitored in real time under a bent or rolled condition.

In the above embodiment, the first strain sensor 103 and the second strain sensor 114 can include an input end and an output end. For example, as shown in FIG. 9, when the first strain sensor 103 is the optical strain sensor composed of a semiconductor grating or a metal grating, the optical strain sensor can include an input end 1032 and an output end 1033 in addition to a grating structure 1031. The input end 1032 can be electrically connected to an external circuit board, and the external circuit board can supply an operating voltage to the optical strain sensor, and the output end 1033 can be electrically connected to an external sensor control unit. Therefore, after the optical strain sensor converts an amount of deformation into physical signals, it can transmit the converted physical signals to the external sensor control unit, so that the sensor control unit can convert the converted physical signals into corresponding readable signals (e.g., voltage signals and current signals) to thereby determine a stress level of a film layer where the optical strain sensor is located.

Specifically, the array substrate 100 further comprises a first connection line and a second connection line, the first connection line and the second connection line are arranged in a same layer as the first strain sensor 103, the first connection line is configured for establishing an electrical connection between the input end of the first strain sensor 103 and the external circuit board, and the second connection line is configured for establishing an electrical connection between the output end of the first strain sensor 103 and the external sensor control unit.

In addition, please continue to refer to FIGS. 6 to 8, the above array substrate 100 can further include at least one pad 115, the at least one pad 115 can be disposed at an edge of the non-display region C2, and can be electrically connected to a driving chip 300 through a flip-chip film 200, and the driving chip 300 can provide scanning signals and data signals to thin film transistors in the array substrate 100 and an operating voltage to the first strain sensor 103 and the second strain sensor 114. Specifically, the pad 115 can include a connection end S, and the pad 115 is electrically connected to the flip-chip film 200 by the connection end S, and in practice, the pad 115 can be bent so as to bend the connection end S of the pad 115, the flip-chip film 200, and the driving chip 300 to a non-light-emitting surface of the array substrate 100, which is advantageous for narrowing a bezel of a display panel.

Different from conventional techniques, in the array substrate of the present embodiment, by providing a stress sensor in an array substrate film layer structure of a flexible display panel, a stress condition of internal film layers of the flexible display panel in a rolled or bent state can be quantitatively tested, and thereby early warning of damage of the flexible display panel can be provided.

Please refer to FIG. 10, which is a schematic process flow diagram illustrating a test method of a film layer stress according to one embodiment of the present application. The test method of the film layer stress can be used in the array substrate of any of the above embodiments. Specifically, an array substrate comprises a base substrate, a first film layer and a first strain sensor disposed on the base substrate, wherein the first film layer is provided with a first mounting groove, and a first strain sensor is disposed in the first mounting groove and is used to detect a stress of the first film layer.

As shown in FIG. 8, the test method of the film layer stress comprises following steps.

Step S81: activating the first strain sensor.

Specifically, the first strain sensor can be supplied with an operating voltage through an external driving circuit (e.g., a flexible circuit board), so that the first strain sensor is activated and enters a working state.

Step S82: bending or rolling the array substrate, and acquiring an amount of change in a detection parameter of the first strain sensor.

In the present embodiment, the first strain sensor is disposed in an area of the base substrate, which is not covered by the first film layer, so that upper and lower film layer structures where the first strain sensor is located can be completely consistent with upper and lower film layer structures where the first film layer is located, and as a result, the first strain sensor can more realistically reflect actual strain and stress conditions of the first film layer inside the array substrate. Specifically, when the array substrate is deformed by rolling, bending, or the like, the first strain sensor is deformed by force and converts an amount of deformation into changes in detection parameters (for example, a resistance change, a capacitance, an inductance, or optical parameters).

Specifically, the first strain sensor 103 can include one or more of a resistive strain sensor, a capacitive strain sensor, an inductive strain sensor, or an optical strain sensor. Among them, the resistive strain sensor can convert the amount of deformation into a resistance change, the capacitive strain sensor can convert the amount of deformation into a capacitance change amount, the inductive strain sensor can convert the amount of deformation into an inductance change rate, and the optical strain sensor can convert the amount of deformation into changes in optical parameters (for example, the optical power, phase, and wavelength).

Step S83: determining a stress of the first film layer according to the amount of change.

The Step S83 specially includes:

Step S831: converting the amount of change to a corresponding current change amount or a corresponding voltage change amount.

Wherein, the amount of change in the detection parameter of the first strain sensor can be converted by an external sensor control unit into a readable electrical signal such as an amount of current change or an amount of voltage change.

Step S832: determining an amount of strain of the first film layer according to the current change amount or the voltage change amount.

Specifically, a Wheatstone bridge can be used to convert the above-mentioned current change amount or voltage change amount into the amount of strain of the first film layer.

Step S833: determining the stress of the first film layer according to the amount of strain of the first film layer.

Specifically, a data table may be established in advance to store a one-to-one correspondence between the amount of strain and the stress of the first film layer, and then the stress corresponding to the current strain of the first film layer can be obtained by consulting the data table.

Different from the prior art, the test method of the film layer stress in the present embodiment can quantitatively test a stress condition of film layers inside a flexible display panel in a bent or rolled state by using a stress sensor in a film layer structure of the array substrate of the flexible display panel and provide early warning of damage of the flexible display panel.

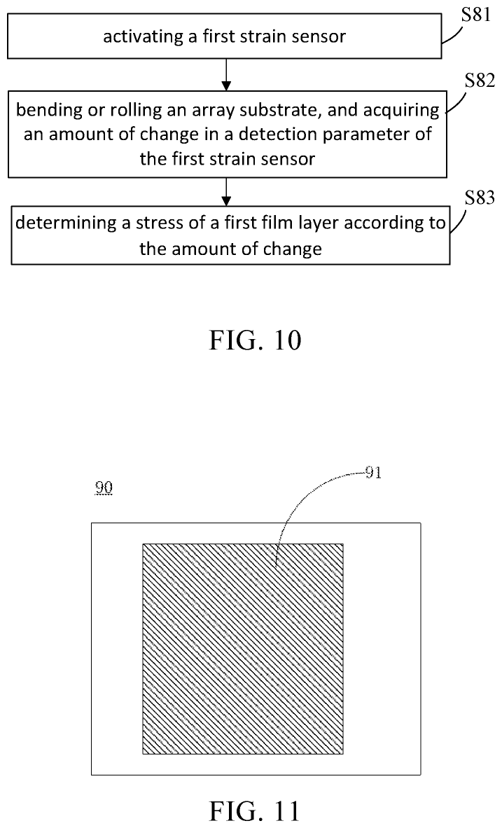

Please refer to FIG. 11, which is a schematic structural diagram of a display panel according to one embodiment of the present application. The display panel 90 comprises an array substrate 91 of any of the above embodiments, wherein the array substrate 91 comprises a base substrate, and a first film layer and a first strain sensor on the base substrate, wherein the first film layer is provided with a first mounting groove, and the first strain sensor is disposed in the first mounting groove and is used to detect a stress of the first film layer.

Different from conventional techniques, in the display panel of the present embodiment, by providing a stress sensor in an array substrate film layer structure of the flexible display panel, a stress condition of internal film layers of the flexible display panel in a rolled or bent state can be quantitatively tested, and early warning of damage of the flexible display panel can be provided.

The above is only the preferable embodiment of the present invention. It should be noted that, for those of ordinary skill in the art, changes and modifications can be made based on the working principles of the present invention. Such changes and modifications should be deemed to be within the protection scope of the present invention.

What is claimed is:

1. An array substrate, comprising:
a base substrate;
a first film layer disposed on the base substrate, a first mounting groove defined in the first film layer; and
a first strain sensor disposed in the first mounting groove, wherein the first strain sensor is configured to detect a stress of the first film layer.

2. The array substrate according to claim 1, wherein the first strain sensor comprises a resistive strain sensor, a capacitive strain sensor, an inductive strain sensor, or an optical strain sensor.

3. The array substrate according to claim 1, wherein material of the first strain sensor is the same as material of the first film layer.

4. The array substrate according to claim 1, wherein the first film layer is a low-temperature polycrystalline silicon (LTPS) layer, a gate layer, a source/drain layer, or an anode layer.

5. The array substrate according to claim 1, wherein the base substrate comprises a bending region, the array substrate comprises one or multiple first strain sensors, and at least one of the first strain sensors is disposed in the bending region.

6. The array substrate according to claim 5, wherein the array substrate comprises multiple first strain sensors, and the first strain sensors are arranged in an array on the base substrate.

7. The array substrate according to claim 1, wherein the first strain sensor comprises an input end and an output end, the input end of the first strain sensor is electrically connected to an external circuit board, the external circuit board is configured to provide an operating voltage to the first strain sensor, and the output end of the first strain sensor is electrically connected to an external sensor control unit.

8. The array substrate according to claim 7, wherein the array substrate further comprises a first connection line and a second connection line, the first connection line and the second connection line are arranged in a same layer as the first strain sensor, the first connection line is configured for establishing an electrical connection between the input end of the first strain sensor and the external circuit board, and the second connection line is configured for establishing an electrical connection between the output end of the first strain sensor and the external sensor control unit.

9. The array substrate according to claim 1, wherein the array substrate further comprises an insulating layer, a second film layer, and a second strain sensor, the insulating layer is disposed on the first film layer and the first strain sensor, the second film layer is disposed on the insulating layer, a second mounting groove is defined in the second film layer, and the second strain sensor is disposed in the second mounting groove, wherein the second strain sensor is configured to detect a stress of the second film layer.

10. A test method of a film layer stress for use in an array substrate, the array substrate comprising: a base substrate; a first film layer disposed on the base substrate, a first mounting groove defined in the first film layer; and a first strain sensor disposed in the first mounting groove, wherein the first strain sensor is configured to detect a stress of the first film layer, the test method of the film layer stress comprising following steps:
activating the first strain sensor;
bending or rolling the array substrate, and acquiring an amount of change in a detection parameter of the first strain sensor; and
determining a stress of the first film layer according to the amount of change.

11. The test method of the film layer stress according to claim 10, wherein determining the stress of the first film layer according to the amount of change comprises:
converting the amount of change to a corresponding current change amount or a corresponding voltage change amount;
determining an amount of strain of the first film layer according to the current change amount or the voltage change amount; and
determining the amount of stress of the first film layer according to the amount of strain of the first film layer.

12. A display panel comprising an array substrate, the array substrate comprising:
a base substrate;
a first film layer disposed on the base substrate, wherein a first mounting groove is defined in the first film layer; and
a first strain sensor disposed in the first mounting groove, wherein the first strain sensor is configured to detect a stress of the first film layer.

13. The display panel according to claim 12, wherein the first strain sensor comprises a resistive strain sensor, a capacitive strain sensor, an inductive strain sensor, or an optical strain sensor.

14. The display panel according to claim 12, wherein material of the first strain sensor is the same as material of the first film layer.

15. The display panel according to claim 12, wherein the first film layer is a low-temperature polycrystalline silicon (LTPS) layer, a gate layer, a source/drain layer, or an anode layer.

16. The display panel according to claim 12, wherein the base substrate comprises a bending region, the display panel comprises one or multiple first strain sensors, and at least one of the first strain sensors is disposed in the bending region.

17. The display panel according to claim 16, wherein the display panel comprises multiple first strain sensors, and the first strain sensors are arranged in an array on the base substrate.

18. The display panel according to claim 12, wherein the first strain sensor comprises an input end and an output end, the input end of the first strain sensor is electrically connected to an external circuit board, the external circuit board is configured to provide an operating voltage to the first strain sensor, and the output end of the first strain sensor is electrically connected to an external sensor control unit.

19. The display panel according to claim 18, wherein the array substrate further comprises a first connection line and a second connection line, the first connection line and the second connection line are arranged in a same layer as the first strain sensor, the first connection line is configured for establishing an electrical connection between the input end of the first strain sensor and the circuit board, and the second connection line is configured for establishing an electrical connection between the output end of the first strain sensor and the sensor control unit.

20. The display panel according to claim 12, wherein the array substrate further comprises an insulating layer, a second film layer, and a second strain sensor, the insulating layer is disposed on the first film layer and the first strain sensor, the second film layer is disposed on the insulating layer, a second mounting groove is defined in the second film layer, and the second strain sensor is defined in the second mounting groove, wherein the second strain sensor is configured to detect a stress of the second film layer.
